(19) United States
(12) Patent Application Publication
(10) Pub. No.: US 2008/0119030 A1
(43) Pub. Date: May 22, 2008

(54) Method for manufacturing thin film semiconductor device

(75) Inventor: Masafumi Kunii, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 11/976,820

(22) Filed: Oct. 29, 2007

(30) Foreign Application Priority Data
Nov. 16, 2006 (JP) 2006-309829

(51) Int. Cl. H01L 21/20

(52) U.S. Cl. 438/479; 257/E21.104

(57) ABSTRACT

According to an embodiment of the present invention, there is provided an improved method for manufacturing a thin film semiconductor device. This method includes the step of depositing a silicon thin film including a crystalline structure on a substrate by plasma CVD in which a silane gas represented by the formula SiₙH₂ₙ₊₂ (n=1, 2, 3, . . . ) and a germanium halide gas are used as a source gas.

### CROSS REFERENCES TO RELATED APPLICATIONS

The present invention contains subject matter related to Japanese Patent Application JP 2006-309829 filed in the Japan Patent Office on Nov. 16, 2006, the entire contents of which being incorporated herein by reference.

### BACKGROUND OF THE INVENTION

1. Field of the Invention

The present invention relates to a method for manufacturing a thin film semiconductor device, and particularly to a method for manufacturing a thin film semiconductor device encompassing a thin film transistor, a display device including a thin film transistor, a photoelectric conversion element typified by a solar cell and sensor employing a semiconductor thin film, and so on.

2. Description of the Related Art

In a flat-panel display such as a liquid crystal display and organic EL display, thin film transistors (TFTs) are provided as elements for driving pixel electrodes. Of the TFTs, a polycrystalline silicon (poly-Si) TFT, which employs poly-Si as its semiconductor thin film, is attracting attention because it allows formation of a drive circuit and it can realize system-on-glass through incorporation of a highly functional circuit in a panel. In order to realize formation of the poly-Si TFT on a low-cost glass substrate, development has been made on a so-called low-temperature poly-Si process, in which the temperature of the manufacturing process is suppressed to 600° C. or lower.

As an existing method for manufacturing a poly-Si TFT by the low-temperature poly-Si process, a method is known in which amorphous silicon is deposited by plasma CVD or the like on a glass substrate having a low melting point and the deposited silicon is irradiated with an energy beam such as a laser beam or electronic beam so as to be crystallized.

As the energy beam for crystallizing amorphous silicon, e.g. an excimer laser with a wavelength of 308 nm obtained through excitation of a XeCl gas is typically used. Industrially, a method is used in which this laser beam is shaped into a linear beam and scan-moved on a glass substrate to thereby crystallize amorphous silicon across the entire surface of the glass substrate.

However, this manufacturing method employing laser annealing uses the laser annealing apparatus having e.g. a precise optical system and a large-scale stabilizing device for stable laser oscillation, which causes increase in the apparatus cost. Furthermore, the limitation of the optical system and oscillation energy of the laser beam imposes certain limitation on the beam size, which makes it difficult to uniformly irradiate a large-area substrate. Therefore, when increase in the substrate size is taken into consideration, the laser annealing is not necessarily preferable in terms of productivity. Moreover, polycrystalline silicon obtained through laser beam crystallization involves a problem. Specifically, the crystal grain size easily varies as the reflection of variation in the laser beam energy, which results in variation in TFT characteristics.

To address this problem, there have been proposed some methods for directly depositing a silicon thin film including a crystalline structure on a substrate without laser annealing.

For example, Japanese Patent Laid-open No. Hei 6-168882 (Patent Document 1) discloses film deposition by plasma CVD in which a silane-fluorosilane-fluorine gas system is used. According to Patent Document 1, a sharp Raman spectrum based on crystalline silicon is observed from a silicon thin film obtained by this method.

Furthermore, Japanese Patent Laid-open No. 2005-243951 (Patent Document 2) discloses film deposition by plasma CVD in which a silicide gas (e.g., silane) and fluorine or halogen fluoride are introduced in a deposition chamber. According to Patent Document 2, in this method, a semi-amorphous silicon thin film having a pillar crystalline structure is formed from the start of the film deposition.

Moreover, Japanese Patent Laid-open No. 2001-68422 (Patent Document 3) discloses a reactive thermal CVD method. Specifically, in this method, an etching gas and a deposition gas are introduced on a heated substrate, so that the deposition gas is thermally activated by the heated substrate in the presence of the etching gas. This causes thermochemical reaction to thereby directly deposit a crystalline semiconductor thin film.

However, for applying the plasma CVD by use of a silane-fluorosilane-fluorine gas system disclosed in Patent Document 1, high power is necessary for decomposing the fluorosilane, which is difficult to decompose. In addition, there is also a need to increase the gas flow rate of the fluorosilane in order to compensate the decomposition of the fluorosilane.

In the plasma CVD employing silane-fluorine disclosed in Patent Document 2, the deposition rate is low because the fluorine gas easily etches silicon. Furthermore, because the reactivity of the fluorine gas is high, merely mixing the silane gas with the fluorine gas yields fluorosilane, and hence high plasma power for decomposing the fluorosilane may be needed.

In the reactive thermal CVD of Patent Document 3, the substrate temperature needs to be at least 400° C., which is equal to the decomposition temperature of disilane as the deposition gas, and needs to be 450° C. or higher for a sufficiently high deposition rate. If the substrate temperature will reach 450° C. or higher, a typical SUS steel CVD chamber is not available but there is a need to design a CVD deposition apparatus based on special heat-resistance specifications. Furthermore, even when the substrate temperature is set to 450° C., the deposition rate in the reactive thermal CVD, which employs no plasma reaction, is as low as about 8 to 9 nm/min.

### SUMMARY OF THE INVENTION

There is a need for an embodiment of the present invention to provide a method for manufacturing a thin film semiconductor device, allowing a crystalline silicon thin film to be deposited on a substrate at a high deposition rate even when the substrate temperature is low. Such a method can industrially put into practical use the direct deposition of a crystalline silicon thin film on a substrate, and a thin film semiconductor device that is manufactured by this method and therefore includes this silicon thin film is permitted to have higher performance.

According to an aspect of the present invention, there is provided a method for manufacturing a thin film semiconductor device that includes a silicon thin film as a semiconductor thin film. In this method, this silicon thin film is deposited by plasma CVD in which a silane gas represented by the formula SiₙH₂ₙ₊₂ (n=1, 2, 3, . . . ) and a germanium halide gas are used as a source gas.

It is confirmed that the plasma CVD employing such a source gas allows deposition of a microcrystalline silicon thin film composed of microcrystalline silicon of which grain size is about several nanometers to 100 nm, as described later in detail in the description of an embodiment of the present invention. Furthermore, it is also confirmed that this plasma deposition method permits a film to be deposited at a high deposition rate even when the substrate temperature is low. Specifically, the above-described microcrystalline silicon thin film is obtained at a substrate temperature lower than 600 to 700° C., which is equivalent to the strain point of a typical glass substrate, such as about 400° C. or lower. In addition, it is also confirmed that film deposition is carried out at a deposition rate about five times that in reactive thermal CVD as a related art.

As described above, the aspect of the present invention allows a crystalline silicon thin film to be deposited on a substrate at a high deposition rate even when the substrate temperature is low. Therefore, direct deposition of a crystalline silicon thin film on a substrate can be put into practical use industrially, and using this silicon thin film can provide a thin film semiconductor device having higher performance.

### BRIEF DESCRIPTION OF THE DRAWINGS

FIG. 1 is a structural diagram showing one example of a film deposition apparatus used in a manufacturing method according to an embodiment of the present invention;

FIGS. 2A and 2B show Raman spectra of microcrystalline silicon thin films obtained by the manufacturing method according to the embodiment;

FIGS. 3A to 3J are sectional views showing manufacturing steps in a first example of a method for manufacturing a thin film semiconductor device to which the embodiment of the present invention is applied;

FIGS. 4A to 4F are sectional views showing manufacturing steps in a second example of the method for manufacturing a thin film semiconductor device to which the embodiment of the present invention is applied;

FIGS. 5A to 5F are sectional views showing manufacturing steps in a third example of the method for manufacturing a thin film semiconductor device to which the embodiment of the present invention is applied;

FIG. 6 is a structural diagram of another thin film transistor (thin film semiconductor device) to which the embodiment of the present invention is applied; and

FIG. 7 is a structural diagram of further another thin film transistor (thin film semiconductor device) to which the embodiment of the present invention is applied.

### DETAILED DESCRIPTION OF THE PREFERRED EMBODIMENTS

An embodiment of the present invention relating to a method for manufacturing a thin film semiconductor device will be described in detail below based on the drawings. In the following, the embodiment will be described in the order of a film deposition apparatus used in a method for manufacturing a thin film semiconductor device, methods for depositing a crystalline silicon thin film by using this deposition apparatus, and methods for manufacturing a thin film semiconductor device to which any of these deposition methods is applied.

### <Film Deposition Apparatus>

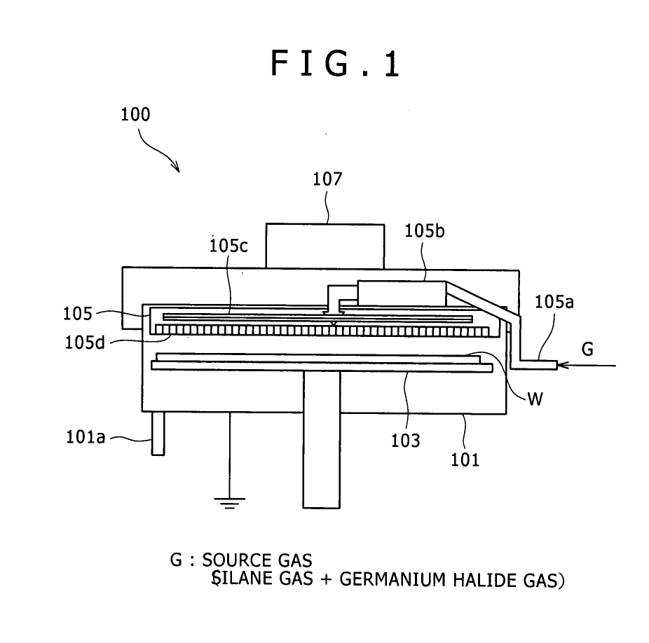

FIG. 1 is an entire structural diagram showing one example of a film deposition apparatus used in manufacturing of a thin film semiconductor device. A deposition apparatus 100 shown in this drawing is a parallel plate plasma CVD apparatus. The deposition apparatus 100 includes a treatment chamber 101 in which film deposition treatment is performed, a stage 103 for fixedly holding a substrate W for which deposition treatment is performed in the treatment chamber 101, an upper electrode 105 disposed corresponding to the stage 103, and a high frequency power supply 107 connected to the upper electrode 105.

The treatment chamber 101 is grounded and provided with an exhaust tube 101a for discharging the inside gas.

The stage 103 serves also as a lower electrode and is disposed in the treatment chamber 101 in such a manner as to be grounded similarly to the treatment chamber 101. This stage 103 serving also as the lower electrode and the upper electrode 105 to be described below function as the parallel plates. The stage 103 may be provided with a temperature controller for heating the substrate W to a predetermined temperature and holding the temperature.

The upper electrode 105 serves also as a shower head for supplying a treatment gas in the treatment chamber 101 and is disposed to face the entire surface of the substrate W fixedly held on the stage 103. A gas inlet tube 105a is connected to the upper electrode 105 and provided with a gas mixing chamber 105b. Gases introduced through the gas inlet tube 105a are supplied in the upper electrode 105 after being mixed in the gas mixing chamber 105b, which contributes to uniform film deposition.

The upper electrode 105 includes a gas dispersing plate 105c and the plane thereof facing the stage 103 is formed as a shower plate 105d. The dispersing plate 105c is to disperse an introduced source gas toward the entire surface of the substrate W, and the shower plate 105d is to uniformly supply the dispersed gas onto the substrate W. Although only one channel of the gas inlet tube 105a is illustrated in the drawing, plural gas channels are provided according to need, in practice.

The high frequency power supply 107 applies high frequency RF power to the upper electrode 105.

The deposition apparatus 100 having the above-described structure allows film deposition by plasma CVD in which source gas plasma is generated above the substrate W. The embodiment of the present invention is not limited to film deposition by use of the parallel plate plasma CVD apparatus shown in this drawing, but can be similarly applied also to another apparatus as long as it permits film deposition by plasma CVD.

### <Deposition Method-1>

A description will be made below about a first example of a method for depositing a crystalline silicon thin film by using the above-described deposition apparatus 100.

Initially, the substrate W is fixedly held on the stage 103 in the treatment chamber 101. Subsequently, the pressure in the treatment chamber 101 is set to 13.3 to 1330 Pa, preferably to 133 to 400 Pa. The temperature of the substrate W is set to 100 to 600° C., preferably to 300 to 450° C.

With the pressure in the treatment chamber 101 and the temperature of the substrate W kept in this manner, high frequency power with a frequency of 10 to 100 MHz, preferably 10 to 30 MHz, is applied from the high frequency power supply 107 to the upper electrode 105. This forms an electric field between the electrode 105 and the lower electrode (stage 103).

Furthermore, under this condition, a source gas is supplied from the gas inlet tube 105a in the treatment chamber 101 and plasma is generated, to thereby perform plasma CVD deposition.

In the present embodiment, this source gas has a feature.

Specifically, as the source gas, a silane gas and a germanium halide gas are supplied in the treatment chamber 101. The silane gas refers to a gas represented by the formula SiₙH₂ₙ₊₂ (n=1, 2, 3, . . . ). As the silane gas, typically monosilane (SiH₄), disilane (Si₂H₆), or trisilane (Si₃H₈) is used. As the germanium halide gas, a germanium fluoride gas such as a germanium tetrafluoride (GeF₄) or germanium difluoride (GeF₂) gas, or a germanium chloride gas such as a germanium tetrachloride (GeCl₄) gas is used.

According to need, an inert gas such as an Ar, He, Ne, Kr, Xe, or N₂ gas or a hydrogen gas may be supplied as a dilution gas from the gas inlet tube 105a to the treatment chamber 101 together with the above-described source gas.

Through the above-described steps, a silicon thin film including a crystalline structure (hereinafter, referred to as a microcrystalline silicon thin film) is deposited by the plasma CVD on the substrate W.

In this film deposition method, the purity of the gas to be used is enhanced to 3N or higher, preferably to 4N, in order to suppress mixing of an impurity in the deposited microcrystalline silicon thin film. Moreover, in order to decrease the concentration of impurity elements such as oxygen, carbon, and nitrogen in the deposited microcrystalline silicon thin film, it is desirable to clean the treatment chamber by carrying out plasma treatment with a cleaning gas (e.g., a fluorine gas, halogen fluoride gas, or NF₃ gas) before the above-described plasma CVD deposition.

A description will be made below about evaluation results on the film quality, deposition rate, and so on of microcrystalline silicon thin films as Samples 1 to 4 obtained by the above-described plasma CVD.

As shown in Table 1, for the source gas, an Si₂H₆ gas (Si₂H₆ 100%, the flow rate was 10 sccm) was used as the silane gas, and a GeF₄ gas (diluted with an Ar gas, GeF₄ 10⁻⁶, the flow rate is shown in Table 1) was used as the germanium fluoride gas. As a dilution gas, an Ar gas (the flow rate was 700 sccm) was used. The pressure in the treatment chamber was set to 270 Pa. The RF power (the RF power supply frequency was 27.12 MHz) was set to 1.2 kW. The substrate temperature was set to 400° C.

TABLE 1

| | | | | | RF | Substrate | | | Deposition |
|---|---|---|---|---|---|---|---|---|---|
| | Si2H6 | GeF4 | Ar | Pressure | power | temperature | | Film | rate |
| | (sccm) | (sccm) | (sccm) | (Pa) | (kW) | (° C.) | Crystallinity | thickness | (nm/min.) |
| Sample 1 | 10 | 5 | 700 | 270 | 1.2 | 400 | Microcrystal + | 410 | 41.0 |
| Sample 2 | | 10 | | | | | Nanocrystal | 400 | 40.0 |
| Sample 3 | | 20 | | | | | | 391 | 39.1 |
| Sample 4 | | 40 | | | | | | 412 | 41.2 |

| | | | | | | |
|---|---|---|---|---|---|---|
| Comparative | 5 | 170 | 0.4 | 350 | Amorphous | — |
| example 1 | | | | | | |
| Comparative | 5 | 270 | 0.1 | | | — |
| example 2 | | | | | | |

The distance between the electrodes in the parallel plate plasma CVD apparatus was 25 nm, and the area of the electrodes was 2500 cm². The deposition time was 10 minutes. As the substrate W, a glass substrate on which a silicon oxide thin film was deposited to a thickness of 100 nm by plasma CVD was used.

Furthermore, as Comparative examples 1 and 2 also shown in Table 1, film deposition was carried out with the pressure in the treatment chamber, the RF power (RF power supply frequency was 27.12 MHz), and the substrate temperature changed.

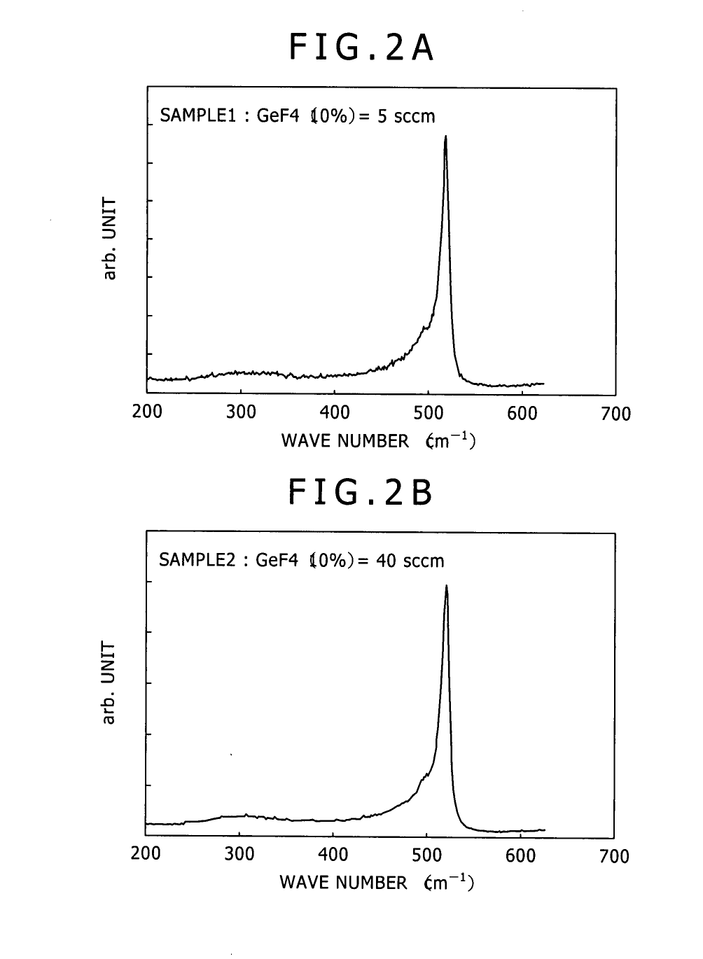

On the thus deposited microcrystalline silicon thin films of Samples 1 to 4, Raman measurement by use of a reference beam having a wavelength of 514 nm was performed. FIG. 2A shows a Raman spectrum obtained through the measurement on Sample 1, and FIG. 2B shows a Raman spectrum obtained through the measurement on Sample 4.

As typified by these Raman spectra, from all of the microcrystalline silicon thin films of Samples 1 to 4, a sharp peak was observed around 518 to 520 cm⁻¹, which is a consequence of the TO phonon mode corresponding to Si—Si bonding that indicates Si including a crystalline structure. The half-value width of the peaks was 9.7 to 10.8 cm⁻¹.

A noteworthy point is that the plasma reaction between Si₂H₆ and GeF₄ used for the deposition of Samples 1 to 4 results in almost no mixing of Ge in the deposited microcrystalline silicon thin film irrespective of the flow rate of GeF₄. If crystalline Ge is contained in Si, a peak attributed to the TO phonon mode of Ge—Ge bonding (around 290 cm⁻¹) and a peak attributed to the TO phonon mode of Si—Ge bonding (400 cm⁻¹) will appear. However, neither of Raman spectra shown in FIGS. 2A and 2B shows these peaks relating to Ge bonding. This clearly proves no mixing of Ge in Si.

Furthermore, as shown in FIGS. 2A and 2B, a slight peak is observed around 500 cm⁻¹ in either Raman spectrum. This peak arises from the shift of a Raman peak due to the crystal size effect and will be attributed to nanocrystalline silicon of which grain size is on the order of several nanometers.

Moreover, in either Raman spectrum, a peak around 480 cm⁻¹ attributed to amorphous silicon is smaller than the peak around 518 to 520 cm⁻¹ corresponding to the TO phonon mode of Si—Si bonding and the peak around 500 cm⁻¹ due to the crystal size effect. This fact proves that the microcrystalline silicon thin films of Samples 1 to 4 contain very little amorphous component.

Furthermore, the surfaces of the microcrystalline silicon thin films of Samples 1 to 4 were observed by using a scanning electron microscope. As a result, it was confirmed that microcrystalline silicon having grain sizes of 20 to 100 nm was grown under any condition. In addition, cross-sectional TEM observation proved that crystal grains having a crystalline structure with a pillar shape (referred to also as a column shape) were grown from the substrate surface.

The above-described results prove that the deposition method of the embodiment allows deposition of a microcrystalline silicon thin film that is composed of nanocrystalline silicon having grain sizes of several nanometers and microcrystalline silicon having grain sizes of 10 to 100 nm.

Furthermore, as shown in Table 1, the deposition rates calculated from the film thicknesses of the microcrystalline silicon thin films of Samples 1 to 4 and the deposition time (10 minutes) were in the range of 39.1 to 41.2 nm/min. This deposition rate is about five times a deposition rate of 8 to 9 nm/min achieved in the reactive thermal CVD (the substrate temperature is 450° C.) disclosed in Patent Document 3.

As described above, the deposition method of the embodiment allows a crystalline silicon thin film to be deposited on a substrate at a deposition rate higher than five times that of reactive thermal CVD even when the substrate temperature is lower than that in the reactive thermal CVD. Consequently, for manufacturing of a high-performance thin film semiconductor device formed by using a crystalline silicon thin film, direct deposition of a crystalline silicon thin film on a substrate can be put into practical use industrially, which greatly contributes to productivity enhancement.

In the above-described deposition method for the silicon thin films of Samples 1 to 4, the substrate temperature was set to 400° C. However, by optimizing the pressure in the treatment chamber (deposition atmosphere), the RF power, the flow rate ratio between the source gas and the dilution gas, and so on, a microcrystalline silicon thin film containing a crystalline component can be deposited even at a lower substrate temperature of about 100 to 300° C. Because film deposition at such a low substrate temperature is possible, merely adding a gas system permits the use of an existing plasma CVD apparatus.

Furthermore, a complicated and expensive apparatus such as a laser crystallization apparatus is unnecessary, which decreases the number of steps and the tact time and thus can reduce the manufacturing cost.

For both Comparative examples 1 and 2 also shown in Table 1, film deposition was carried out with the RF power (the RF power supply frequency was 27.12 MHz) set to as low as 0.4 kW and 0.1 kW, respectively. In a silicon thin film obtained through such film deposition, a crystalline structure was not found but an amorphous silicon thin film was formed. As is apparent from this fact, in plasma CVD deposition in which a silane gas and a germanium halide gas are supplied as a source gas, keeping the RF power at a somewhat high value permits deposition of a silicon thin film containing a crystalline structure.

Other advantages besides the above-described ones are also found. Specifically, the Raman spectra shown in FIGS. 2A and 2B prove that the film internal stress is small in a microcrystalline silicon thin film obtained by the deposition method according to the embodiment of the present invention. More specifically, in a Raman spectrum from a typical microcrystalline silicon thin film containing a crystalline component, due to the film internal stress, a peak will appear around 510 cm⁻¹, which is on the smaller wavenumber side compared with 520 cm⁻¹ corresponding to a original peak in a Raman spectrum from a single-crystal silicon. However, as for a microcrystalline silicon thin film obtained in the embodiment of the present invention, a peak in the Raman spectrum appears extremely near 520 cm⁻¹, which clearly proves the small internal stress.

Therefore, it is possible to form a microcrystalline silicon thin film in which variation in the carrier mobility due to the film stress is small. As a result, thin film semiconductor devices employing this microcrystalline silicon thin film are permitted to have uniform characteristics relating to the carrier mobility.

In addition, as a result of the above-described cross-sectional TEM observation, it was found that crystal grains having a crystalline structure with a pillar shape (referred to also as a column shape) were grown from the substrate surface. This fact indicates that the deposition method according to the embodiment of the present invention offers a microcrystalline silicon thin film of which crystallinity on the bottom side is favorable in particular. Therefore, for example, if a thin film transistor employing this microcrystalline silicon thin film as its channel layer is formed as a bottom-gate transistor, a partial portion of the microcrystalline silicon thin film having more favorable crystallinity can be used as the channel forming part (i.e., the part on the gate electrode side), which can surely enhance the carrier mobility advantageously.

Furthermore, the germanium halide gas used as the source gas in the present deposition method does not react with the silane gas at a low temperature. Thus, these gases are uniformly mixed with each other without reaction in the gas mixing chamber 105b. Consequently, the source gas component can be uniformly supplied onto a large-area substrate, which can achieve a microcrystalline silicon thin film having a uniform film quality. The term “low temperature” used here refers to a gas temperature of 400° C. or lower when Si₂H₆ and GeF₄ are used as one example.

When the germanium halide gas used as the source gas in the present deposition method is e.g. GeF₄, the dissociation energy of GeF₄→GeF₃+F is as low as 5.0 eV. In contrast, in the case of e.g. SiF₄ as a fluorosilane gas, the dissociation energy of SiF₄→SiF₃+F is 10.8 eV. The dissociation energy of GeF₄ is half this energy. This permits efficient gas decomposition with low plasma power, which can achieve reduction in the manufacturing cost due to the lowering of the plasma power and enhancement in the use efficiency of the source gas.

In the above-described deposition method of the embodiment, almost no Ge is mixed in the deposited microcrystalline silicon thin film although a silane gas and a germanium halide gas are used as the source gas. This feature can be explained based on the following reaction systems.

Specifically, as a reaction system of gas-phase reaction between Si₂H₆ and GeF₄, which is complicated, used as the source gas in the plasma CVD deposition in the present embodiment, the reaction system represented by Formula (1) is generally known.

SiH₃SiH₃+GeF₄→SiH₃GeF₃+SiH₃F (1)

As reactions subsequent to that of Formula (1), the reactions represented by Formulas (2) to (4) will occur.

SiH₃GeF₃→SiH₃F+GeF₂ (2)

SiH₃GeF₃→SiH₂+GeF₃H (3)

SiH₃GeF₃→SiH₃+GeF₃ (4)

In these reaction systems, Si—Ge bonding would be easily broken. In other words, in the gas-phase reaction between Si₂H₆ and GeF₄, Ge is not contained in the end product but GeF₄ behaves as a catalyst eventually. This will be the reason why mixing of Ge in a microcrystalline silicon thin film obtained by the deposition method of the embodiment of the present invention is not found. The SiH3 radical generated in the reaction system represented by Formula (4) is generally considered as a major radical for the growth of a silicon film.

On the other hand, it is known that in the reactive thermal CVD disclosed in Patent Document 3, about several percentages to several tens of percentages of Ge are mixed in a deposited thin film typically, although there is a tendency that the amount of mixed Ge becomes smaller depending on the condition such as the gas flow rate. This Ge mixing can be proved from the fact that a Raman spectrum from the deposited thin film will show a sharp peak around a wavenumber of 290 cm⁻¹ or 400 cm⁻¹. In contrast, in the method according to the embodiment of the present invention, almost no mixing of Ge is found greatly characteristically.

Furthermore, in e.g. the plasma reaction between SiH₄ and GeH4 for deposition of a SiGe film, amorphous SiₓGe₁₋ₓ (0≦x≦1) is deposited, and the Ge content (i.e., the value of x) changes depending on the flow rate ratio between SiH₄ and GeH4. In contrast, the deposition method according to the embodiment of the present invention is greatly different from known plasma reaction in that the Ge content is almost zero irrespective of the flow rate of GeF₄ as described above.

### <Deposition Method-2>

A description will be made below about film deposition of an n-type microcrystalline silicon thin film or a p-type microcrystalline silicon thin film in which an n-type or a p-type impurity (dopant) is introduced in advance, as a second example of the method for depositing a microcrystalline silicon thin film by using the above-described deposition apparatus 100. The overlapping part with the first example is omitted.

In the second example, besides the source gas shown in the first example, a dopant gas containing an impurity is introduced from the gas inlet tube 105a to the treatment chamber 101. The other steps may be the same as those in the first example.

For the dopant gas, in deposition of an n-type microcrystalline silicon thin film, phosphine (PH₃), which contains phosphorous (P) as an n-type impurity, is used. In deposition of a p-type microcrystalline silicon thin film, diborane (B2H6), which contains boron (B) as a p-type impurity, is used.

This deposition method allows direct deposition of a microcrystalline silicon thin film and activation of an impurity (dopant) contained in the deposited microcrystalline silicon thin film.

It is preferable that the treatment chamber 101 in which a microcrystalline silicon thin film containing an impurity in the activated state is deposited as described above be provided separately from the treatment chamber 101 for deposition of a microcrystalline silicon thin film containing no impurity. This separation prevents an impurity from entering a microcrystalline silicon thin film containing no impurity. In stacking of a microcrystalline silicon thin film containing no impurity with a microcrystalline silicon thin film containing an impurity, it is preferable to use a multi-chamber plasma CVD apparatus and transfer the substrate W among the respective deposition treatment chambers without breaking a vacuum in order to prevent impurity mixing from the air.

### <Method for Manufacturing Thin Film Semiconductor Device-1>

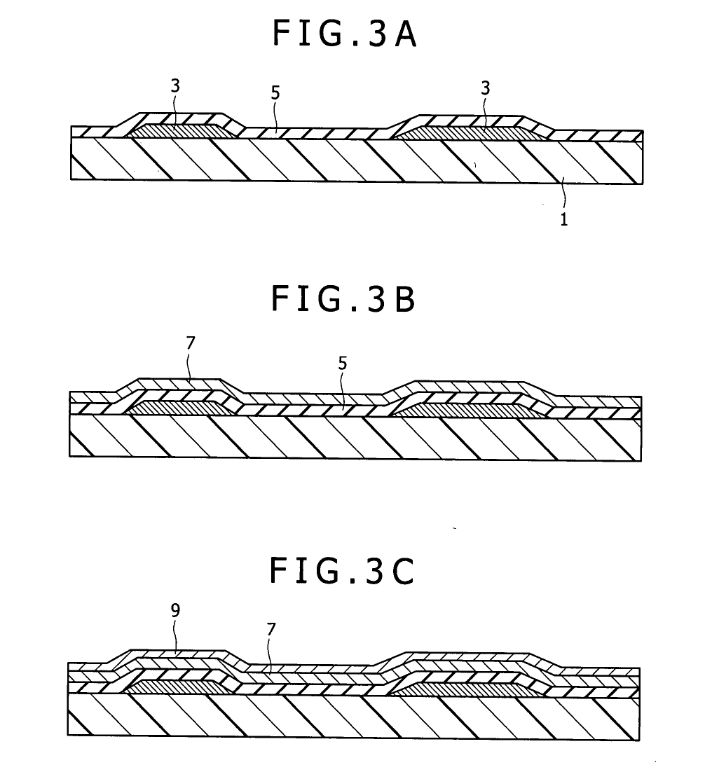

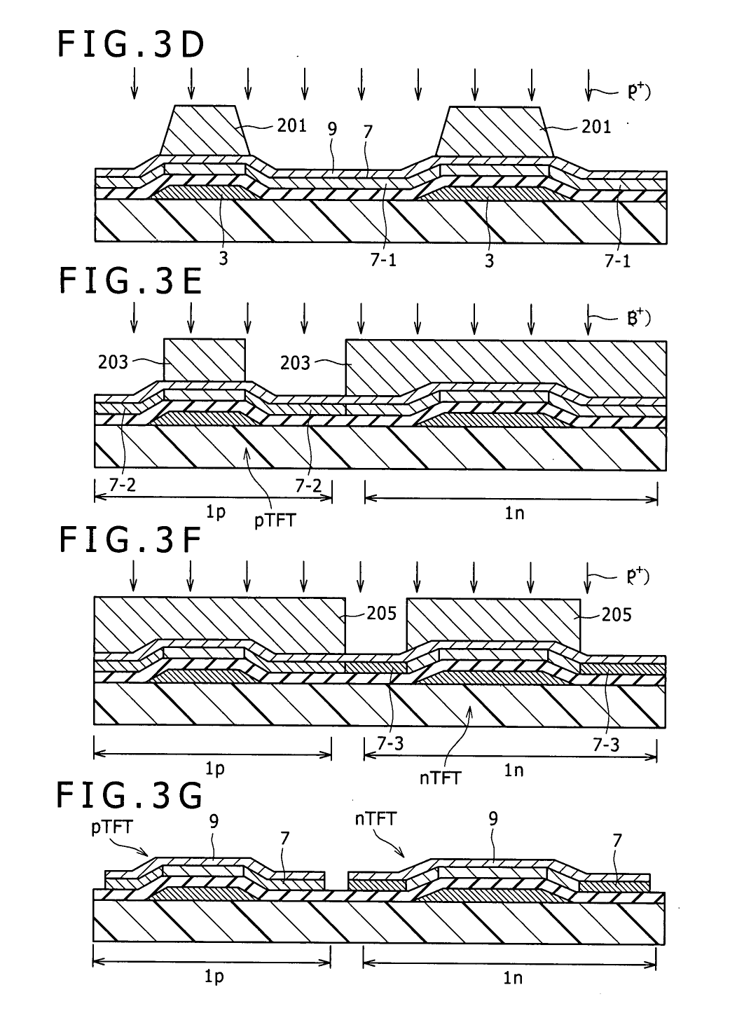

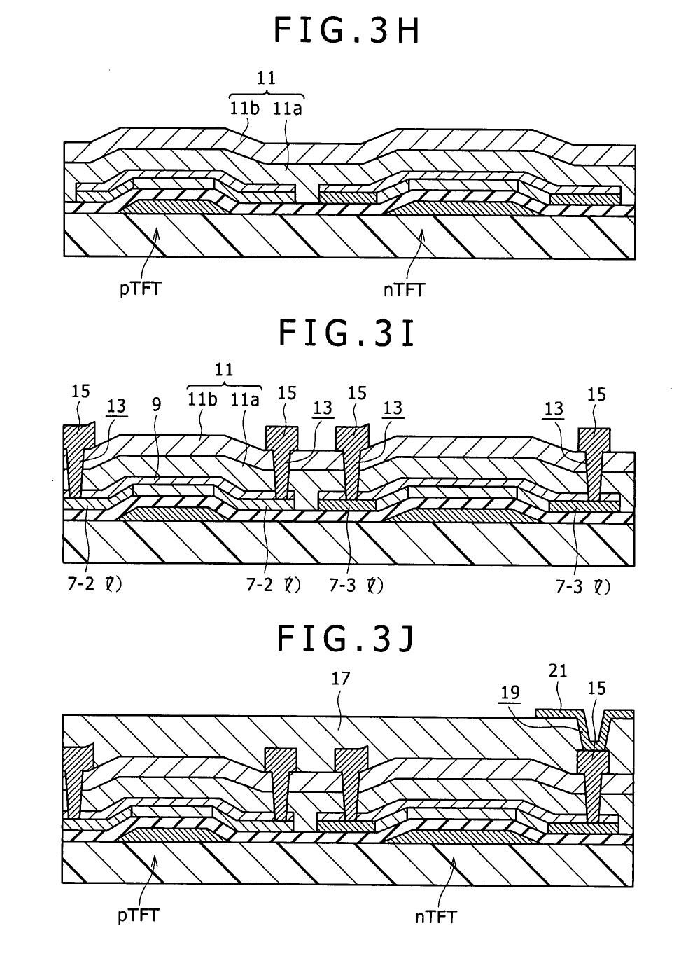

A first example of a method for manufacturing a thin film semiconductor device to which the above-described deposition method is applied will be described below based on the sectional views of FIGS. 3A to 3J showing manufacturing steps. In the first example, the embodiment of the present invention is applied to fabrication of a drive panel for a display device that includes planar-type bottom-gate TFTs having a CMOS structure.

Initially, as shown in FIG. 3A, an insulating substrate 1 is prepared. As the substrate 1, e.g. AN 100 by Asahi Glass, Code 1737 by Corning, or the like is accordingly used.

Gate electrodes 3 are pattern-formed on this substrate 1. In this example, a metal film such as a Mo, W, Ta, or Cu film is deposited by sputtering, and the deposited metal film is patterned into the gate electrodes 3. The film thickness of the gate electrodes (metal film) is 30 to 200 nm.

Subsequently, by a film deposition method such as plasma CVD or LPCVD, a silicon nitride (SiNx) film serving as a gate insulating film 5 is deposited on the gate electrodes 3 to a thickness of 10 to 50 nm, and a silicon oxide (SiOx) film is deposited thereon to a thickness of 10 to 100 nm. Through this step, the gate insulating film 5 having a multilayer structure formed of the silicon nitride film and the silicon oxide film is formed.

Thereafter, as shown in FIG. 3B, a microcrystalline silicon thin film 7 containing no impurity is deposited by the CVD deposition method of the embodiment described in <Deposition Method-1>. In this example, the microcrystalline silicon thin film 7 having a film thickness of 10 to 100 nm, preferably 40 nm, is deposited.

This microcrystalline silicon thin film 7 will serve as the active layers of TFTs. It is desirable that the concentration of impurity elements such as oxygen, carbon, and nitrogen contained in these active layers be at most 3×1020 cm⁻³. In order to suppress the concentration of these impurity elements, as described above in <Deposition Method-1>, plasma etching is carried out with supply of a cleaning gas (e.g., a fluorine gas, halogen fluoride gas, or NF₃ gas) for cleaning of the treatment chamber, and then the CVD deposition is performed.

To enhance the crystallinity of the deposited microcrystalline silicon thin film 7, any of the following measures may be implemented for the film 7: a pulse laser such as an excimer laser, gas laser such as an Ar laser, solid-state laser such as a YAG laser, semiconductor laser such as a GaN laser, rapid thermal annealing (RTA) employing a xenon (Xe) arc lamp or the like, and energy irradiation such as plasma jet irradiation.

Subsequently to the deposition of the microcrystalline silicon thin film 7, as shown in FIG. 3C, a silicon oxide film 9 is deposited by plasma CVD or the like on the microcrystalline silicon thin film 7 to a film thickness of about 1 to 100 nm.

Thereafter, according to need, B⁺ ions are implanted into the microcrystalline silicon thin film 7 at a dose amount of about 0.1 E12 to 4 E12/cm² in order to control the threshold voltage Vth of the thin film transistors to be formed in this example. In this ion implantation, the acceleration voltage for the ion beam is set to about 20 to 200 keV.

Referring next to FIG. 3D, by backside exposure from the substrate 1 side with use of the gate electrodes 3 as the mask, a resist pattern 201 is formed on the silicon oxide thin film 9. Subsequently, by ion implantation with use of this resist pattern 201 as the mask, impurity introduction for forming LDD diffusion layers 7-1 of an n-type MOS transistor in the microcrystalline silicon thin film 7 is carried out. In this ion implantation, e.g. P⁺ ions are used and mass-separated or non-mass-separated ion implantation is performed at an implantation dose amount of 6 E12 to 5 E13/cm² with an acceleration voltage of about 20 to 200 keV. After the ion implantation, the resist pattern 201 is removed.

Referring next to FIG. 3E, a resist pattern 203 that covers a partial portion of a p-channel region 1p above the gate electrode 3 and an n-channel region 1n is formed. Subsequently, by ion implantation with use of this resist pattern 203 as the mask, impurity introduction for forming source/drain 7-2 of a p-channel thin film transistor is performed. In this ion implantation, e.g. B⁺ ions are used and mass-separated or non-mass-separated ion implantation is performed at an implantation dose amount of 1 E14 to 3 E15/cm² with an acceleration voltage of about 5 to 100 keV. This forms the p-channel thin film transistor (pTFT). After the ion implantation, the resist pattern 203 is removed.

Referring next to FIG. 3F, a resist pattern 205 that covers the p-channel region 1p and a partial portion of the n-channel region in above the gate electrode 3 is formed. Subsequently, by ion implantation with use of this resist pattern 205 as the mask, impurity introduction for forming source/drain 7-3 of the n-channel thin film transistor is performed. In this ion implantation, e.g. P⁺ ions are used and implanted at an implantation dose amount of 1 E15 to 3 E15/cm² with an acceleration voltage of about 10 to 200 keV, to thereby form the n-channel thin film transistor (nTFT). After the ion implantation, the resist pattern 205 is removed.

After the above-described ion implantation, the impurity introduced in the microcrystalline silicon thin film 7 is activated by rapid thermal annealing (RTA) such as infrared lamp heating or furnace annealing, laser annealing, furnace annealing in an N₂ atmosphere at 600° C. or lower, or the like.

Thereafter, as shown in FIG. 3G, the silicon oxide film 9 and the microcrystalline silicon thin film 7 are simultaneously subjected to pattern-etching, so that each of the thin film transistors pTFT and nTFT is shaped into an island pattern.

Subsequently, as shown in FIG. 3H, a silicon oxide thin film 11a and a silicon nitride thin film 11b containing hydrogen are deposited in that order in such a way that the respective thin film transistors pTFT and nTFT each shaped into an island pattern are covered, to thereby form an interlayer insulating film 11 having a two-layer structure. The deposition of these films is performed by e.g. plasma CVD.

At the timing after the formation of the interlayer insulating film 11, a hydrogenation step is carried out. Specifically, in this step, by annealing treatment in an inert gas, forming gas, or the like, the hydrogen in the interlayer insulating film 11, particularly in the silicon nitride film 11b, is diffused into the microcrystalline silicon thin film 7. As the annealing condition, e.g. 400° C. and two hours are preferable. This hydrogenation step eliminates dangling bonds in the microcrystalline silicon thin film 7, and thus can enhance TFT characteristics. This hydrogenation step is not limited to the hydrogen diffusion from the silicon nitride thin film 11b but can be achieved also by exposing the microcrystalline silicon thin film 7 in a hydrogen plasma atmosphere.

Referring next to FIG. 3I, contact holes 13 reaching the sources/drains 7-2 and 7-3 in the microcrystalline silicon thin film 7 are formed in the interlayer insulating film 11 and the silicon oxide film 9. Subsequently, on the interlayer insulating film 11, interconnect electrodes 15 that are connected via the contact holes 13 to the sources/drains 7-2 and 7-3 are formed. The formation of the interconnect electrodes 15 is carried out by depositing an interconnect electrode material such as Al—Si by sputtering and patterning the deposited film.

Referring next to FIG. 3J, a planarization insulating film 17 composed of e.g. an acrylic organic resin is formed by coating to a film thickness of about 1 μm. Subsequently, a contact hole 19 reaching the interconnect electrode 15 is formed in this planarization insulating film 17. Furthermore, a pixel electrode 21 that is connected via this contact hole 19 to the interconnect electrode 15 is formed on the planarization insulating film 17. The pixel electrode 21 is formed by depositing e.g. indium tin oxide (ITO) as a transparent conductive material by sputtering and patterning it.

When the pixel electrode 21 is composed of ITO, the pixel electrode 21 is annealed in a nitrogen atmosphere at about 220° C. for 30 minutes.

In the present example, in the drive panel for the display device, a pixel transistor for driving the pixel electrode is the n-channel thin film transistor nTFT, and the peripheral circuit has a CMOS structure. As a part of the peripheral circuit, only the p-channel thin film transistor pTFT is shown.

Through the above-described steps, the drive panel is completed. If the display device is e.g. a liquid crystal display, after the above-described steps, an alignment layer is formed in such a manner as to cover the pixel electrode 21. Subsequently, a counter substrate obtained by depositing on a substrate a counter electrode and an alignment layer in that order is prepared, and then a liquid crystal is sealed between the alignment layers to thereby complete the display device. On the other hand, when the display device is an organic EL display employing organic electroluminescent elements, organic layers including a luminescent layer are stacked over the pixel electrode. Furthermore, an electrode is provided over the organic layers, and this electrode is covered by a protective film according to need, to thereby complete the display device.

In the above-described manufacturing method, the above-described deposition method is applied to deposition of the microcrystalline silicon thin film 7. This allows achievement of the bottom-gate thin film transistors pTFT and nTFT each employing, as the channel layer, the microcrystalline silicon thin film 7 that is deposited at a high deposition rate proper for industrial practical use. Because these thin film transistors pTFT and nTFT employ the crystalline silicon thin film 7 as the channel layer, they have carrier mobility higher than that of amorphous silicon TFTs and thus can offer a higher-performance circuit. Therefore, the display device of which drive circuit is formed by using such thin film transistors pTFT and nTFT has higher performance.

Furthermore, because the microcrystalline silicon thin film 7 is deposited at a low temperature, it is possible to form the gate electrodes 3 by using a metal having a comparatively low melting point, such as Al, Cu, Ag, or Au.

Furthermore, without using a complicated and expensive apparatus such as a laser crystallization apparatus, thin film transistors can be manufactured by using only a plasma CVD apparatus, metal sputtering apparatus, exposure apparatus, and etching apparatus. This feature means that TFTs employing a microcrystalline silicon thin film can be manufactured through a process equivalent to one for amorphous silicon TFTs. Specifically, the embodiment of the present invention permits substrate size to increase similar to that for amorphous silicon TFT displays, of which substrate size is being increased in recent years, and can be applied even to a large-size glass substrate of 2-m-square or more, which is generally considered as a size for the G8 generation or later. Thus, the embodiment allows production of a large-size display device having a diagonal length of 50 inches or more, which provides industrially advantageous effects.

In the present embodiment, the thin film transistors pTFT and nTFT each have a single-gate structure. However, the thin film transistor nTFT serving as a pixel transistor may have a multi-gate structure, in which plural gates are provided between the source region and the drain region. Characteristically, the off-current of a multi-gate TFT can be reduced more easily compared with a single-gate TFT, and hence the multi-gate TFT is useful as a microcrystalline silicon TFT, of which off-current is larger than that of an amorphous silicon TFT.

### <Method for Manufacturing Thin Film Semiconductor Device-2>

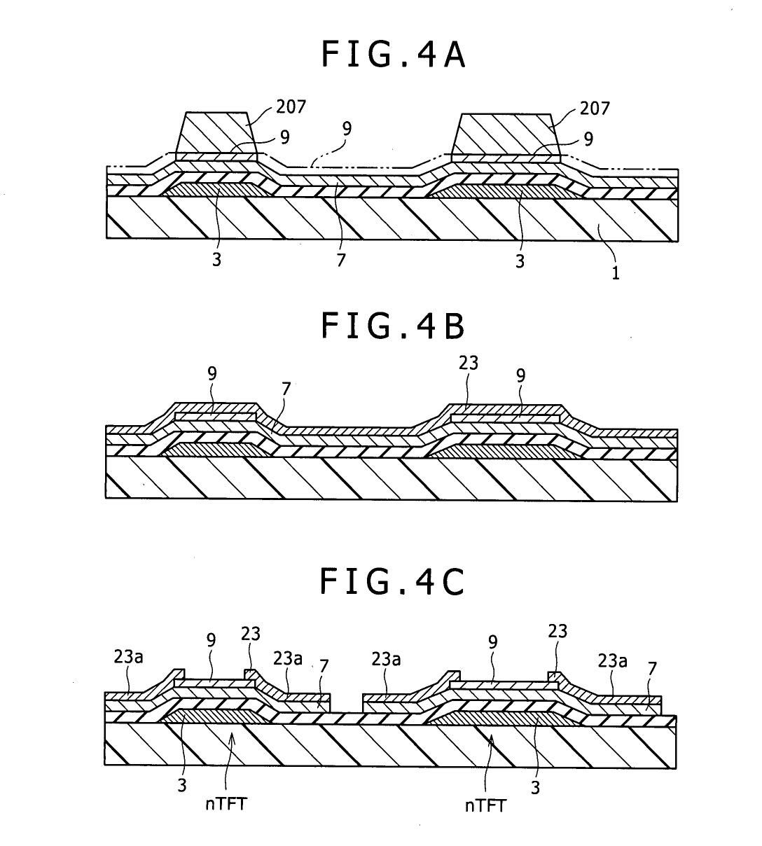

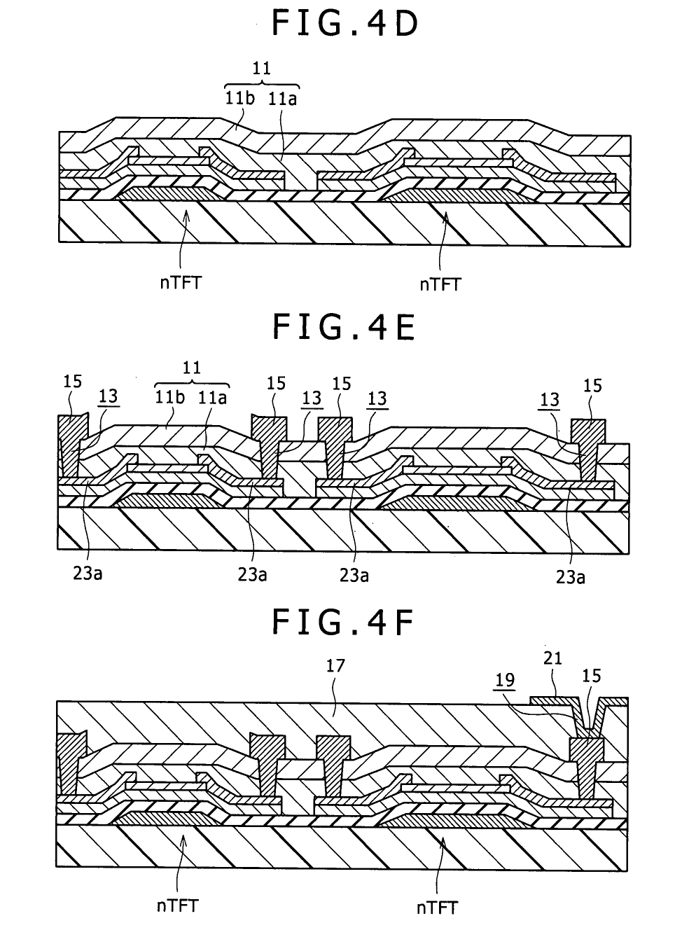

A second example of the method for manufacturing a thin film semiconductor device to which the above-described deposition method is applied will be described below based on the sectional views of FIGS. 4A to 4F showing manufacturing steps. In the second example, the embodiment of the present invention is applied to fabrication of a drive panel for a display device that includes channel-stop-type bottom-gate TFTs having a single-channel structure including only n-channels.

Initially, by the same procedure as that in the first example described by using FIGS. 3A to 3C, the following steps are carried out. Specifically, gate electrodes 3 are pattern-formed on an insulating substrate 1, and a gate insulating film 5 covering the gate electrodes 3 is deposited. Furthermore, a microcrystalline silicon thin film 7 containing no impurity is deposited by the CVD deposition method of the embodiment described in <Deposition Method-1>, and then a silicon oxide thin film 9 is deposited. Thereafter, ion implantation for the purpose of controlling the threshold voltage Vth of the thin film transistors to be formed is performed according to need.

After these steps, as shown in FIG. 4A, by backside exposure from the substrate 1 side with use of the gate electrodes 3 as the mask, a resist pattern 207 is formed on the silicon oxide thin film 9. Subsequently, by etching with use of this resist pattern 207 as the mask, the silicon oxide thin film 9 on the microcrystalline silicon thin film 7 is so removed that only the silicon oxide thin film 9 above the gate electrodes 3 is left. After this etching, the resist pattern 207 is removed.

Subsequently, as shown in FIG. 4B, a microcrystalline silicon thin film 23 containing an activated impurity is deposited by the CVD deposition method of the embodiment described in <Deposition Method-2>. In this example, the microcrystalline silicon thin film 23 having a film thickness of 10 to 500 nm is deposited. In this deposition, phosphine (PH₃) is used as a dopant gas to thereby form n-type microcrystalline silicon 21 (hereinafter, referred to as the n-type microcrystalline silicon thin film 23). The deposition of this n-type microcrystalline silicon thin film 23 is carried out in a treatment chamber different from the treatment chamber for depositing the microcrystalline silicon thin film 7 containing no impurity. If diborane (B2H6) is used as the dopant gas, a p-type microcrystalline silicon thin film containing an activated p-type impurity is obtained.

The microcrystalline silicon thin film 7 formed first will serve as the channel layer 7, and the n-type microcrystalline silicon thin film 23 containing the dopant will serve as the source/drain layer 23.

Referring next to FIG. 4C, the source/drain layer 23 and the channel layer 7 are simultaneously etched to match with the pattern of the source/drain layer 23, so that each thin film transistor region is shaped into an island pattern.

The etching is stopped by the silicon oxide film 9 serving as an etching stop layer, and therefore sources/drains 23a and the channel layer 7 are simultaneously formed in one step. This forms channel-stop-type thin film transistors nTFT each having an n-channel.

After the above-described steps, the steps shown in FIGS. 4D to 4F are carried out similarly to those in the first example described by using FIGS. 3H to 3J.

Specifically, referring initially to FIG. 4D, an interlayer insulating film 11 having a two-layer structure formed of a silicon oxide thin film 11a and a silicon nitride thin film 11b containing hydrogen is deposited to cover the formed thin film transistors nTFT. Thereafter, hydrogenation treatment is carried out.

Subsequently, as shown in FIG. 4E, contact holes 13 reaching the sources/drains 23a are formed in the interlayer insulating film 11, and interconnect electrodes 15 connected to the sources/drains 23a are formed.

Thereafter, as shown in FIG. 4F, a planarization insulating film 17 is formed by coating, and a contact hole 19 reaching the interconnect electrode 15 of the thin film transistor nTFT used as a pixel transistor is formed. Subsequently, a pixel electrode 21 that is connected via this contact hole 19 to the interconnect electrode 15 is formed.

Through the above-described steps, the drive panel is completed. The procedure for manufacturing a display device subsequent to the above-described steps is similar to that in the first example.

Also in the manufacturing method of the second example, the above-described film deposition method is applied to the deposition of the microcrystalline silicon thin film 7, and thus the same advantages as those in the first example are achieved. In addition, the above-described film deposition method is applied also to the deposition of the n-type microcrystalline silicon thin film 23 serving as the sources/drains 23a, which can enhance the efficiency of the manufacturing step for channel-stop-type bottom-gate TFTs. Furthermore, because the microcrystalline silicon thin film 7 and the n-type microcrystalline silicon thin film 23 are deposited at a low temperature, it is possible to form the gate electrodes 3 by using a metal having a comparatively low melting point, such as Al, Cu, Ag, or Au.

In the second example, channel-stop-type bottom-gate TFTs that have a single-channel structure including only n-channels are formed. However, TFTs having a CMOS structure can also be formed by depositing the microcrystalline silicon thin film 23 twice for n-type and p-type films. Furthermore, combination with a p-channel thin film transistor having another structure is also available.

### <Method for Manufacturing Thin Film Semiconductor Device-3>

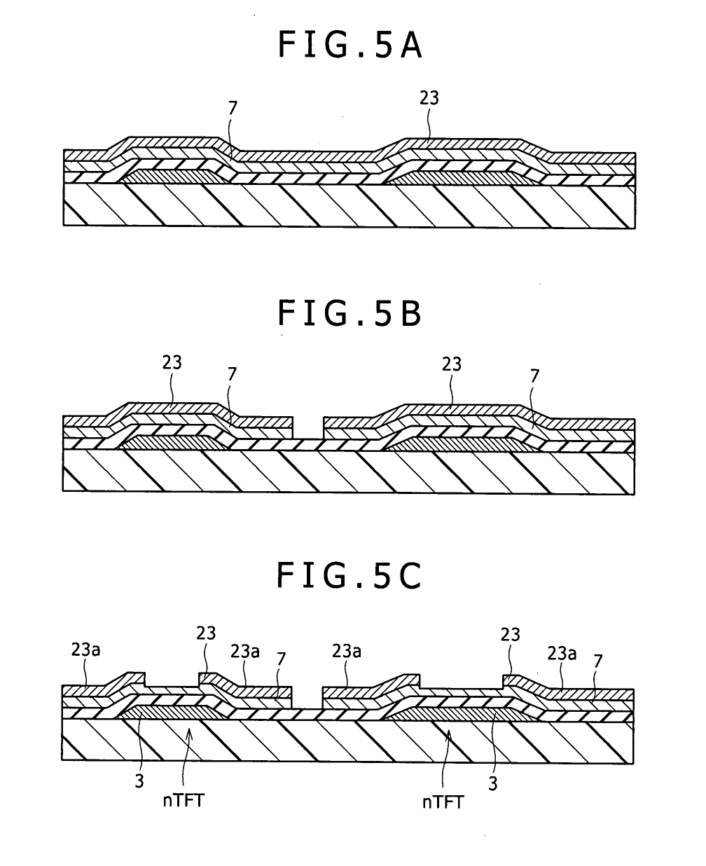

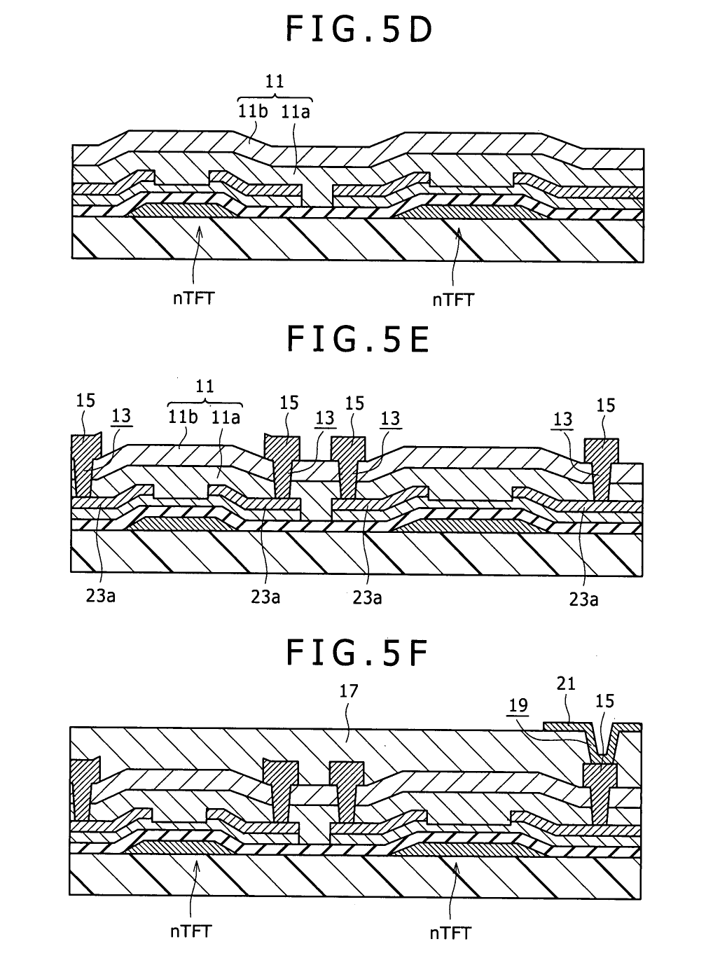

A third example of the method for manufacturing a thin film semiconductor device to which the above-described deposition method is applied will be described below based on the sectional views of FIGS. 5A to 5F showing manufacturing steps. In the third example, the embodiment of the present invention is applied to fabrication of a drive panel for a display device that includes channel-etched-type bottom-gate TFTs having a single-channel structure including only n-channels.

Initially, by the same procedure as that in the first example described by using FIGS. 3A to 3C, the following steps are carried out. Specifically, gate electrodes 3 are pattern-formed on an insulating substrate 1, and a gate insulating film 5 covering the gate electrodes 3 is deposited. Furthermore, a microcrystalline silicon thin film 7 containing no impurity is deposited by the CVD deposition method of the embodiment described in <Deposition Method-1>. Thereafter, ion implantation for the purpose of controlling the threshold voltage Vth of the thin film transistors to be formed is performed according to need.

Subsequently, as shown in FIG. 5A, a microcrystalline silicon thin film 23 containing an activated impurity is deposited by the CVD deposition method of the embodiment described in <Deposition Method-2>. In this example, the microcrystalline silicon thin film 23 having a film thickness of 10 to 200 nm is deposited. In this deposition, phosphine (PH₃) is used as a dopant gas to thereby form n-type microcrystalline silicon 23 (hereinafter, referred to as the n-type microcrystalline silicon thin film 23). The deposition of this n-type microcrystalline silicon thin film 23 is carried out in a treatment chamber different from the treatment chamber for depositing the microcrystalline silicon thin film 7 containing no impurity. However, it is preferable that, after the deposition of the microcrystalline silicon thin film 7, the substrate be transferred without breaking a vacuum in the treatment chamber for the deposition of the n-type microcrystalline silicon thin film 23. If diborane (B2H6) is used as the dopant gas, a p-type microcrystalline silicon thin film containing an activated p-type impurity is obtained.

The microcrystalline silicon thin film 7 formed first will serve as the channel layer 7, and the n-type microcrystalline silicon thin film 23 containing the dopant will serve as the source/drain layer 23.

Referring next to FIG. 5B, the source/drain layer 23 and the channel layer 7 are simultaneously pattern-etched, so that each thin film transistor region is shaped into an island pattern.

Subsequently, as shown in FIG. 5C, the source/drain layers 23 each shaped into an island pattern are so pattern-etched as to be each divided into two portions above the gate electrode 3, so that sources/drains 23a are formed. This forms channel-etched-type thin film transistors nTFT each having an n-channel.

After the above-described steps, the steps shown in FIGS. 5D to 5F are carried out similarly to those in the first example described by using FIGS. 3H to 3J.

Specifically, referring initially to FIG. 5D, an interlayer insulating film 11 having a two-layer structure formed of a silicon oxide thin film 11a and a silicon nitride thin film 11b containing hydrogen is deposited to cover the formed thin film transistors nTFT. Thereafter, hydrogenation treatment is carried out.

Subsequently, as shown in FIG. 5E, contact holes 13 reaching the sources/drains 23a are formed in the interlayer insulating film 11, and interconnect electrodes 15 connected to the sources/drains 23a are formed.

Thereafter, as shown in FIG. 5F, a planarization insulating film 17 is formed by coating, and a contact hole 19 reaching the interconnect electrode 15 of the thin film transistor nTFT used as a pixel transistor is formed. Subsequently, a pixel electrode 21 that is connected via this contact hole 19 to the interconnect electrode 15 is formed.

Through the above-described steps, the drive panel is completed. The procedure for manufacturing a display device subsequent to the above-described steps is similar to that in the first example.

Also in the manufacturing method of the third example, the above-described film deposition method is applied to the deposition of the microcrystalline silicon thin film 7, and thus the same advantages as those in the first example are achieved. In addition, the above-described film deposition method is applied also to the deposition of the n-type microcrystalline silicon thin film 23 serving as the sources/drains 23a, which can enhance the efficiency of the manufacturing step for channel-etched-type bottom-gate TFTs. Furthermore, similarly to the second example, because the microcrystalline silicon thin film 7 and the n-type microcrystalline silicon thin film 23 are deposited at a low temperature, it is possible to form the gate electrodes 3 by using a metal having a comparatively low melting point, such as Al, Cu, Ag, or Au.

In the third example, channel-etched-type bottom-gate TFTs that have a single-channel structure including only n-channels are formed. However, TFTs having a CMOS structure can also be formed by depositing the microcrystalline silicon thin film 23 twice for n-type and p-type films. Furthermore, combination with a p-channel thin film transistor having another structure is also available.

In all of the above-described first to third examples, the pixel electrode 21 is formed on the planarization insulating film 17. However, the planarization insulating film 17 is not necessarily required but the pixel electrode 21 may be formed directly on the interlayer insulating film 11.

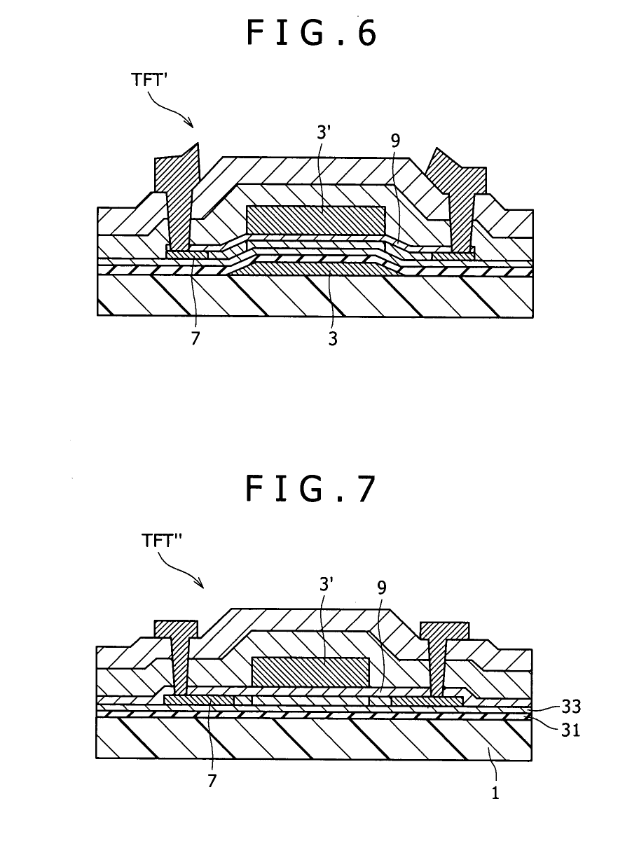

Furthermore, in all of the above-described first to third examples, the embodiment of the present invention is applied to fabrication of bottom-gate thin film transistors. However, the embodiment of the present invention can be applied also to fabrication of a dual-gate thin film transistor TFT′ shown in FIG. 6. In the fabrication of this transistor TFT′, the same steps as those in the first example are carried out until the step described with FIG. 3G is completed, and then a second gate electrode 3′ is formed above the microcrystalline silicon thin film 7 deposited by using <Deposition Method-1> in the embodiment of the present invention with the intermediary of the silicon oxide film 9 (gate insulating film). This gate electrode 3′ is so disposed that the microcrystalline silicon thin film 7 is interposed between the gate electrodes 3 and 3′. The upper and lower gate electrodes 3 and 3′ may be supplied with the same potential, or alternatively may be supplied with different potentials to thereby intentionally control the threshold voltage.

The embodiment of the present invention can be applied also to fabrication of a top-gate thin film transistor TFT″ shown in FIG. 7. In the fabrication of this transistor TFT″, a silicon nitride film 31 serving as a buffer layer and a silicon oxide film 33 are deposited in that order on a substrate 1, and then a microcrystalline silicon thin film 7 is deposited on the silicon oxide film 33 by using <Deposition Method-1> in the embodiment of the present invention. Subsequently, this microcrystalline silicon thin film 7 is patterned into an island shape, and then a gate insulating film formed of a silicon oxide film 9 is deposited to cover the patterned film 7. Furthermore, a gate electrode 3′ is formed on the gate insulating film. Subsequently, by ion implantation in which this gate electrode 3′ and a resist pattern formed according to need are used as the mask, an impurity is introduced into the microcrystalline silicon thin film 7 to thereby form LDD diffusion layers and source/drain.

The above-described first to third examples have dealt with fabrication of a display device employing thin film transistors to which the method for manufacturing a thin film semiconductor device according to the embodiment of the present invention is applied. However, the embodiment of the present invention can be applied not only to a display device including thin film transistors but also to a method for manufacturing another thin film semiconductor device employing a crystalline silicon thin film, such as a photoelectric conversion element typified by a solar cell, photo sensor, and so on, in a similar manner.

It should be understood by those skilled in the art that various modifications, combinations, sub-combinations and alternations may occur depending on design requirements and other factors insofar as they are within the scope of the appended claims or the equivalent thereof.

What is claimed is:

1. A method for manufacturing a thin film semiconductor device, the method comprising the step of
depositing a silicon thin film including a crystalline structure on a substrate by plasma CVD in which a silane gas represented by a formula SiₙH₂ₙ₊₂ (n=1, 2, 3, . . . ) and a germanium halide gas are used as a source gas.

2. The method for manufacturing a thin film semiconductor device according to claim 1, wherein
the germanium halide gas is at least one of GeF₂, GeF₄, and GeCl₄.

3. The method for manufacturing a thin film semiconductor device according to claim 1, wherein
a dopant gas is further used as the source gas to thereby deposit a silicon thin film containing an activated dopant.

4. The method for manufacturing a thin film semiconductor device according to claim 3, wherein
a gas containing an n-type or p-type impurity is used as the dopant gas.

5. The method for manufacturing a thin film semiconductor device according to claim 1, wherein
in the step of depositing a silicon thin film, the substrate is heated.
